(19) United States
(12) Patent Application Publication
(10) Pub. No.: US 2006/0003235 A1
(43) Pub. Date: Jan. 5, 2006

(54) Semiconductor manufacturing method and an exposure mask

(75) Inventor: Fumitoshi Sugimoto, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Fujitsu Limited, Kawasaki (JP)

(21) Appl. No.: 10/991,461

(22) Filed: Nov. 19, 2004

(30) Foreign Application Priority Data
Jul. 2, 2004 (JP) 2004-196963

(51) Int. Cl. G03F 7/00

(52) U.S. Cl. 430/5; 430/311

(57) ABSTRACT

A semiconductor manufacturing method is disclosed. The method includes a lithography process having an exposure step for projecting an image of a mask pattern of a mask onto a photo resist layer using exposure light. The mask pattern includes a first pattern having a light transparency characteristic corresponding to a circuit pattern, and a second pattern having an inverted light transparency characteristic arranged within and spaced apart from the first pattern.

### BACKGROUND OF THE INVENTION

1. Field of the Invention

The present invention relates to a semiconductor manufacturing method and an exposure mask used in a lithography process for manufacturing semiconductor devices.

2. Description of the Related Art

The integration of semiconductor devices has constantly increased by four times every three years, because MOS type logic devices require higher functionality and memory devices require larger storing capacity. The improvement in the integration is provided by miniaturizing the design size of semiconductor devices. The miniaturization is very advantageous because it increases operating speed and reduces power consumption in semiconductor devices, and therefore it is desired more and more.

Under this situation, downsizing to 0.1 μm or less has been required as the minimum processing size of semiconductor devices, for example a wiring pitch, gate clearance, etc., and manufacturing processes of semiconductor devices are becoming more and more difficult.

Especially, lithography technology is confronted with much more difficulty. In lithography technology, a circuit pattern formed in a mask is transferred to a resist film of a semiconductor substrate using ultraviolet light generated by an exposure apparatus. The resist film is then developed to form the circuit pattern in the resist film. Etching is performed based on the circuit pattern, to form circuit elements such as gate electrodes and wirings. An ArF excimer laser having a wavelength of 0.193 μm is used as an ultraviolet light source.

Recently, the minimum processing size of semiconductor devices became smaller than the wavelength of light sources of exposure apparatuses. Even if image reduction projection is employed to increase the numerical aperture, resolution limit is exceeded. Therefore, there exists a problem that edge positions and shapes of the exposed pattern on the resist film are deformed, that is, the pattern formed in the mask cannot be accurately transferred onto the resist film.

If a mask pattern 101 as shown by the chain line in FIG. 1 is used, end portions of actual wiring 102 formed on a resist film retreat or are put back, and corner portions thereof are rounded, as shown by the solid line in FIG. 1. This phenomenon is called “shortening”. This shortening phenomenon is becoming much more remarkable as designed wiring widths are reduced. If the amount of the shortening exceeds tolerances, bad connections or short circuits of wirings occur.

A variety of technologies (for example, in the patent references cited below) are proposed to inhibit the shortening phenomenon due to this optical proximity effect. For example, an Optical Proximity Correction (OPC) method has been proposed. In the OPC method, a mask pattern is broadened more than a designed wiring pattern at a place where shortening occurs. Alternatively, dummy patterns are arranged around a place where shortening occurs, in order to inhibit the shortening.

For example, as shown in FIG. 2A, four correction patterns 104 called “hammer heads” or “Serif” are added at corners of wiring pattern 103. Alternatively, as shown in FIG. 2B, many correction patterns 106 are arranged around ends of wiring patterns 105 to inhibit the shortening.
Patent reference 1: Japanese Laid-Open Patent Application 10-198048
Patent reference 2: Japanese Laid-Open Patent Application 11-95406

In the method shown in FIG. 2A, however, when plural wiring patterns 103 are arranged in parallel and close to each other, there is not enough room to admit required correction patterns 104, resulting in the shortening not being inhibited enough. If the correction patterns 104 are extremely extended, they become connected to each other, which creates another problem.

In the method shown in FIG. 2B, when the wiring patterns 105 are arranged close to each other, there is also not enough room to accept required correction patterns 106, especially at the circle region B, resulting in the same problem as in FIG. 2A.

### SUMMARY OF THE INVENTION

Accordingly, the present invention is made in view of the above-mentioned problems, and aims at offering a semiconductor manufacturing method and an exposure mask that inhibit the shortening problem and bad connections and short circuits of wiring in lithography processes.

According to one aspect of the present invention, a semiconductor manufacturing method including a lithography process having an exposure step for projecting an image of a mask pattern of a mask onto a photo resist layer using exposure light is provided. In the method, the mask pattern comprises: a first pattern having a light transparency characteristic, corresponding to a circuit pattern; and a second pattern having an inverted light transparency characteristic, arranged within and spaced apart from the first pattern.

According to another aspect of the present invention, a method for manufacturing a semiconductor device including a first region having close gate patterns and a second region having sparse gate patterns, including a lithography process having an exposure step for projecting an image of a mask pattern of a mask onto a photo resist layer of the semiconductor device using exposure light is provided. In the method, the mask pattern comprises: in a region corresponding to the first region, a first pattern being light shielding and corresponding to the gate electrode patterns, and a second pattern being light transparent and arranged within and spaced apart from the first pattern; and in a region corresponding to the second region, a third pattern being light shielding and corresponding to the gate electrode patterns; wherein a width of the first pattern is larger than a width of the third pattern.

According to another aspect of the present invention, a method for manufacturing a semiconductor device including a first region having close wiring patterns and a second region having sparse wiring patterns, including a lithography process having an exposure step for projecting an image of a mask pattern of a mask onto a photo resist layer of the semiconductor device using exposure light is provided. In the method, the mask pattern comprises: in a region corresponding to the first region, a first pattern being light transparent and corresponding to the wiring patterns, and a second pattern being light shielding and arranged within and separated from the first pattern; and in a region corresponding to the second region, a third pattern being light transparent and corresponding to the wiring patterns; wherein a width of the first pattern is larger than a width of the third pattern.

According to the present invention, the shortening phenomenon can be effectively inhibited.

Features and advantages of the present invention are set forth in the description that follows, and in part will become apparent from the description and the accompanying drawings, or may be learned by practice of the invention according to the teachings provided in the description.

### BRIEF DESCRIPTION OF THE DRAWINGS

FIG. 1 shows a prior art mask pattern and its wiring pattern formed on a resist film.

FIG. 2A shows prior art correction hammerhead patterns;

FIG. 2B shows another set of prior art correction patterns;

FIGS. 3A-3C illustrate the principle of the present invention;

FIG. 4 is a plan view of a mask pattern according to a first embodiment of the present invention;

FIG. 5A shows a mask pattern and its formed wiring pattern according to a first example of the first embodiment;

FIG. 5B shows a prior art comparison sample mask pattern and its formed wiring pattern;

FIG. 6 is a chart illustrating the relations between shortening and the width of an auxiliary pattern;

FIG. 7A shows mask patterns and their simulated wiring patterns according to the embodiment;

FIG. 7B shows mask patterns and their simulated wiring patterns according to the comparison sample;

FIGS. 8A-8D show alternative mask patterns according to a first alternative example of the first embodiment;

FIG. 9 is a plan view of a second alternative example of the first embodiment;

FIG. 10 is a plan view of mask patterns having close and sparse patterns;

FIGS. 11A-11C illustrate a lithography process according to a second embodiment of the present invention.

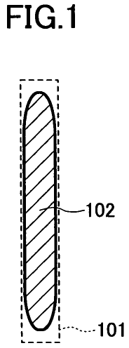

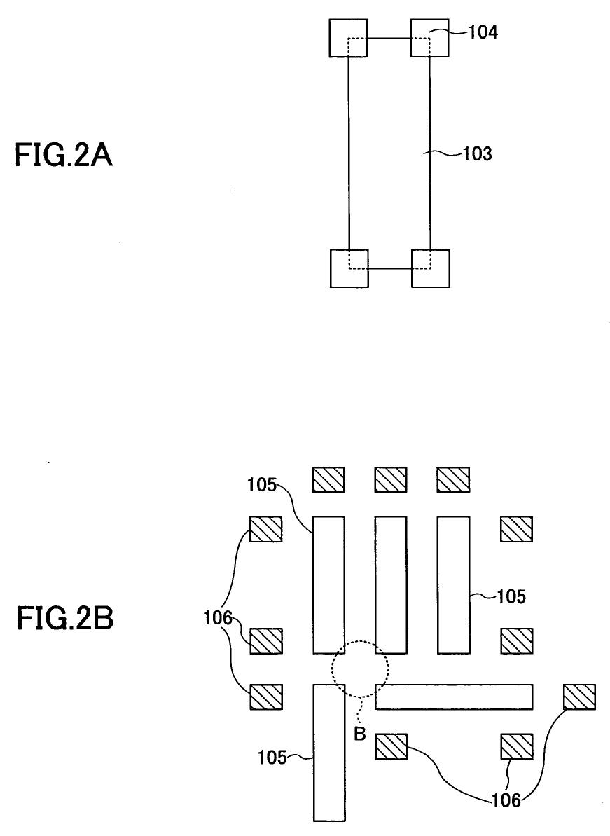

### DESCRIPTION OF THE PREFERRED EMBODIMENTS

In the following, embodiments of the present invention are described with reference to the accompanying drawings.

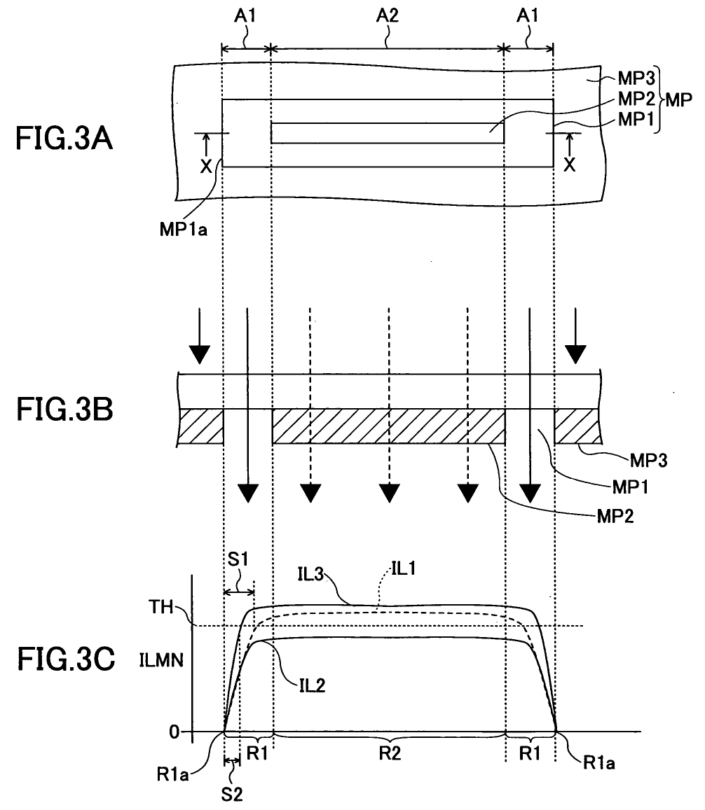

FIGS. 3A-3C illustrate the principle of the present invention. FIG. 3A is a top plan view of an exposure mask according to the present invention. FIG. 3B is a cross-sectional side view of the exposure mask. FIG. 3C illustrates illumination distribution on a resist layer surface.

Referring to FIG. 3A, a mask pattern MP formed in an exposure mask comprises a first pattern MP1 and a second pattern MP2. The first pattern MP1 has first mask regions A1 at ends thereof and a second mask region A2 at the center thereof, as shown in FIG. 3A. The second pattern MP2 is placed within the first pattern MP1, and in the second mask region A2.

In this case, the first pattern MP1 is transparent to light. The second pattern MP2 and the region outside of the first pattern MP1 have light shielding characteristics. Another mask pattern having an inverted transparent characteristic is also included in the present invention, but its explanation is omitted.

Referring to FIGS. 3B and 3C, if no second pattern MP2 is provided, illumination on a resist film (not shown) onto which an image of the mask pattern MP is projected, is represented by a chain line IL1 in FIG. 3C. Exposure light transmitted through the first region A1 of the first pattern MP1 illuminates a region R1 corresponding to the region A1. Upon reaching R1a, the illumination decreases because of the proximity effect by the edge MP1a of the first pattern MP1. Illumination on a region R2 corresponding to the second mask region A2 is higher than the region R1, because of less proximity effect. Supposing a threshold value for enough exposure is TH as shown in FIG. 3C, shortening occurs in a region where the illumination is lower than TH. The shortening amount is represented by S1.

On the other hand, when the second pattern MP2 is provided within the first pattern MP1, the light transmitted through the second mask region A2 is partially shielded by the second pattern MP2. The second pattern MP2 is small enough so that no image of the second pattern MP2 can be projected on the resist layer, and therefore the light transmitted outside of the second pattern MP2 is diffracted and distributed over the whole region R2 on the resist layer. Therefore, the illumination distribution IL2 in the penumbra region R2 is even, and is lower than the illumination distribution IL1.

On the other hand, since the second pattern MP2 is not formed in the first mask region A1, the illumination on the region R1 is substantially the same as in the illumination distribution IL1.

Under this condition, when the intensity of the light source is increased, resultant illumination IL3 becomes larger proportionally. Then the shortening portion where the illumination distribution IL3 is lower than TH becomes smaller. That is, the shortening amount S2 is smaller than S1.

In this manner, the present invention can suppress the shortening effectively. Although FIG. 3 utilizes illumination only for simplicity, the actual exposure amount is determined by (exposure X time). Therefore, instead of increasing the intensity of the light source, exposure time can be lengthened, or sensitivity can be increased.

### First Embodiment

A mask pattern according to a first embodiment of the present invention is explained below.

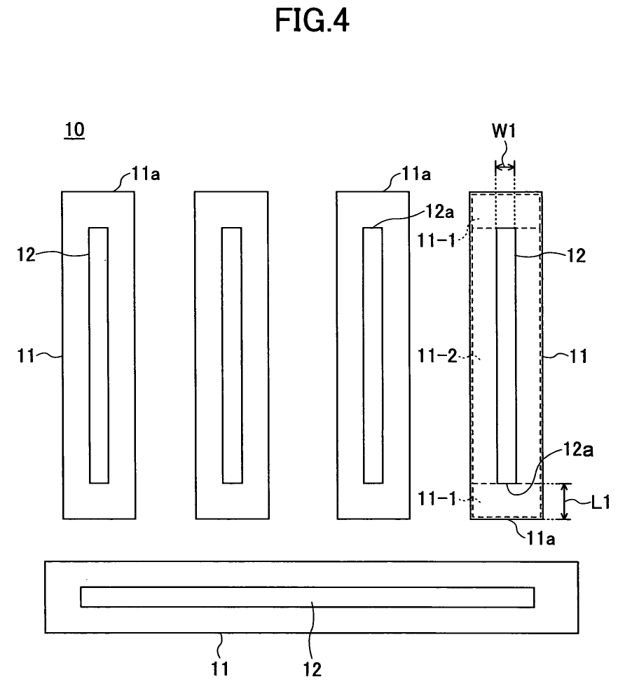

FIG. 4 is a plan view of a mask pattern according to the first embodiment of the present invention. The mask pattern shown in FIG. 4 is, for example, a mask pattern of an exposure mask used in forming a wiring layer on a semiconductor device.

Referring to FIG. 4, the mask pattern 10 comprises wiring patterns 11 and auxiliary patterns 12 formed within the wiring patterns 11. Four rectangular patterns 11 are placed in parallel, and one rectangular pattern 11 is placed perpendicular to the four patterns. Ultraviolet light is shielded outside of the wiring patterns 11 and transmits through the wiring patterns 11.

The auxiliary patterns 12 are formed within the wiring patterns 11, and configured so as to shield ultraviolet light. Each of the wiring patterns 11 has first regions 11-1 at the longitudinal ends 11a thereof and a second region 11-2 between the first regions. The auxiliary patterns 12 are formed in the second regions 11-2. The auxiliary patterns 12 are placed in parallel to the wiring patterns 11 and spaced apart from the sides of the wiring patterns 11. As shown in FIG. 4, the first regions 11-1 lie between the ends of the wiring patterns 11 and the ends of the auxiliary patterns 12.

The width W1 of each of the auxiliary patterns 12 is determined so as not to form an image on a resist film (not shown) that is an image-formation plane onto which the mask pattern 10 is transferred by exposure. By defining the auxiliary patterns 12 in this manner, ultraviolet light transmitting through the wiring patterns 11 is diffused to regions on the image-formation plane corresponding to the auxiliary patterns 12, and its intensity of illumination is lowered compared with a case where no auxiliary pattern 12 is provided.

On the other hand, there is no auxiliary pattern 12 in the first regions 11-1 at the ends of the wiring patterns 11. Therefore, the intensity of illumination is not lowered at regions on the image-formation plane corresponding to the first regions, and is the same as in a case where no auxiliary pattern 12 is provided, because the intensity of illumination is determined by the proximity effect in outer regions of the wiring patterns 11. Accordingly, by providing the auxiliary patterns 12, the intensity of illumination is relatively increased at the regions on the image-formation plane corresponding to the first regions 11-1 compared to the regions on the image-formation plane corresponding to the second region 11-2 due to the above explained principle. The amount of exposure (referred to as “exposure amount on light receiving face” herein) becomes equal over a larger area, resulting in inhibiting the shortening at the ends 11a of the wiring patterns.

The appropriate width W1 of the auxiliary patterns 12 is determined depending on projecting resolution of the exposure device. A reduced width W1 projected onto the image-forming plane is preferably in the range of 2%-20% of the wavelength of the light source. If the reduced width is larger than 20%, the auxiliary patterns 12 may form images. If the reduced width is smaller than 2%, the equality of the illumination is degraded. For example, if an excimer laser having a wavelength of 193 μm is used as a light source, a reduced width W1 of the auxiliary pattern 12 projected onto the image-forming plane is preferably in the range of 4 nm-40 nm, and more preferably in the range of 15 nm-40 nm.

The length of any portion of the mask pattern 10 means a reduced length projected onto the image-forming plane unless otherwise defined. If an exposure device has a reduction ratio of 4:1 for projecting, the length of any portion of the mask pattern is reduced to ¼ on the image-forming plane. In this specification, width direction lengths mean lengths in the shorter side direction of rectangles.

A distance L1 between the ends 12a of the auxiliary patterns 12 and the ends 11a of the wiring patterns 11 is appropriately selected depending on the wavelength of light source to be used for exposure, the configuration, and layout of the wiring patterns 11. For example, if an ArF excimer laser (wavelength: 193 nm) is used as a light source, and widths of the wiring patterns are 90 nm, then the distance L1 is preferably in the range of 50 nm-200 nm.

It is preferable that the auxiliary patterns 12 be placed substantially at the center of the widths of the wiring patterns 11, so as to prevent the images of wiring patterns 11 projected on the image-forming plane from decreasing in width.

The mask pattern 10 having the auxiliary patterns 12 within the wiring patterns 11 according to this embodiment can effectively inhibit the shortening problem, even if the wiring patterns 11 are arranged so closely that no hammer head can be provided. The mask patterns 10 according to this embodiment can still be utilized under conditions where the spaces between the wiring patterns 11 become shorter and the wavelength of exposure devices becomes shorter.

In the mask pattern 10 of the exposure mask according to this embodiment, the inside of the wiring patterns 11 is light transparent and the region outside of the wiring patterns 11 and the auxiliary patterns have shielding characteristics. However, a mask pattern having inverted light transparency can be used. That is, the inside of the wiring patterns 11 can have shielding characteristics and the region outside of the wiring patterns 11 and the auxiliary patterns 12 can be light transparent. In this case, the light transmitting through the auxiliary patterns 12 diffuses and illumination is increased at the middle portion rather than at the ends of the image-formed wiring patterns 11, resulting in equal illumination distribution over the wiring patterns 11. Therefore, by lowering the amount of light source power (brightness) multiplied by exposure time (referred to as “exposure amount of light source” herein), the shortening problem can be inhibited. Such mask patterns can be utilized in forming gate layers as gate electrodes of MOS transistors, for example, and are explained in more detail in a second embodiment below.

### FIRST EXAMPLE

A wiring pattern was formed on a resist film applied on a silicon substrate using an exposure mask according to the first embodiment of the present invention.

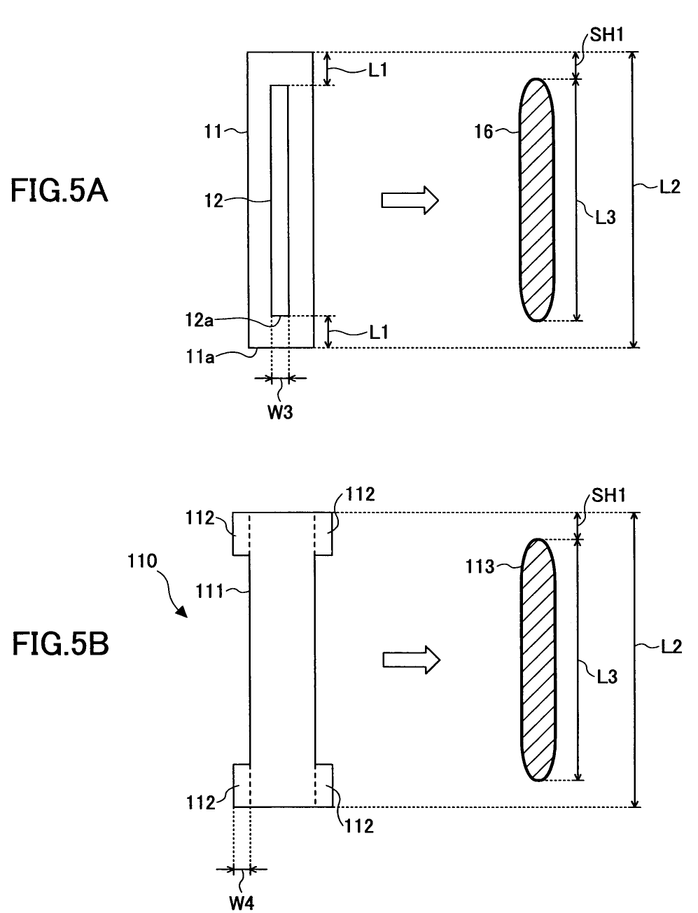

FIG. 5A shows a mask pattern having an auxiliary pattern and a wiring pattern formed in accordance with the first embodiment. FIG. 5b shows a prior art mask pattern having hammer heads and a wiring pattern formed for comparison.

Referring to FIG. 5A, a mask pattern according to the first embodiment comprises a wiring pattern 11 and an auxiliary pattern 12 placed inside of the wiring pattern 11. A reduced longitudinal length L2 of the wiring pattern 11 projected onto a resist film is 750 nm. A reduced width of the wiring pattern 11 projected onto a resist film is 90 nm. A reduced longitudinal length of the auxiliary pattern 12 is 650 nm. A reduced width W3 of the auxiliary pattern 12 is in the range of 4 nm-15 nm. A distance L1 between the ends 11a of the wiring pattern 11 and the ends 12a of the auxiliary pattern 12 is defined as to be 50 nm. For comparison purposes, a mask having no auxiliary pattern (the width W3 is 0) was also formed.

An exposure device used an ArF excimer laser (wavelength: 193 nm) as a light source and a reducing projection system having a reduction rate of ¼ (mask pattern size:image-formed pattern size=4:1). A 250 nm thickness positive type chemically amplified resist film was applied on a silicon substrate, exposed and developed to form an aperture of wiring pattern 16 in the resist film.

The exposure amount of the light source was selected so as to minimize the amount of shortening, which is explained below. For example, the exposure amount of the light source in a case where the width W3 of the auxiliary pattern is 15 nm, was increased by 25% compared to the no auxiliary pattern case.

As shown on the right side of FIG. 5A, an amount of shortening SH1 is defined as to be a distance between the ends of the mask pattern and the ends of the formed wiring pattern 16. That is, the amount of shortening SH1=(reduced length L2 of the mask pattern projected onto an image-forming plane−length L3 of wiring pattern 16 formed on the resist film)/2.

Comparing Sample

As shown in FIG. 5B, a mask pattern 110 not in accordance with the present invention comprises a wiring pattern 111 having the same size as the first example and four auxiliary patterns (hammer heads) 112 formed at four corners of the wiring pattern 111. A longitudinal length L2 of the wiring pattern 111 is the same as the first example. Longitudinal lengths of the auxiliary patterns 112 are 50 nm, widths W4 are 0 nm-15 nm. The conditions of the exposure device and resist film, etc., are the same as in the first example.

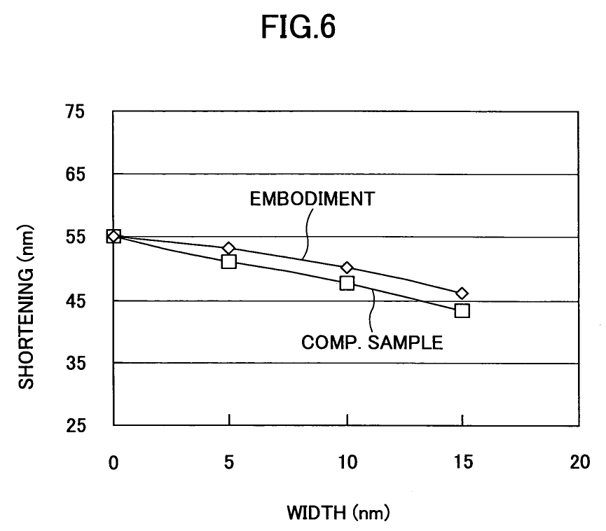

FIG. 6 illustrates relations between shortening amount and auxiliary pattern width in both the first example and the comparison sample. In FIG. 6, diamonds represent the shortenings in the first example and squares represent the shortenings in the comparison sample.

Referring to FIG. 6, it is understand that the wider the auxiliary pattern width is, the less the shortening amount is in both the first example and the comparison sample. The first example gives a substantially equal shortening amount compared to the comparison sample.

In the comparison sample, when plural wiring patterns are arranged in parallel, the wider the auxiliary pattern W4 is, the shorter the space between adjacent wiring patterns becomes. In the first example, when plural wiring patterns are arranged in parallel, even if the auxiliary pattern W3 becomes wider, the space between adjacent wiring patterns is constant. Therefore, the first embodiment is advantageous because it can prevent short circuits effectively, especially when the wiring pitch becomes shorter.

Simulation was performed for both the first example and the comparison sample under the condition that plural wiring patterns are closely arranged.

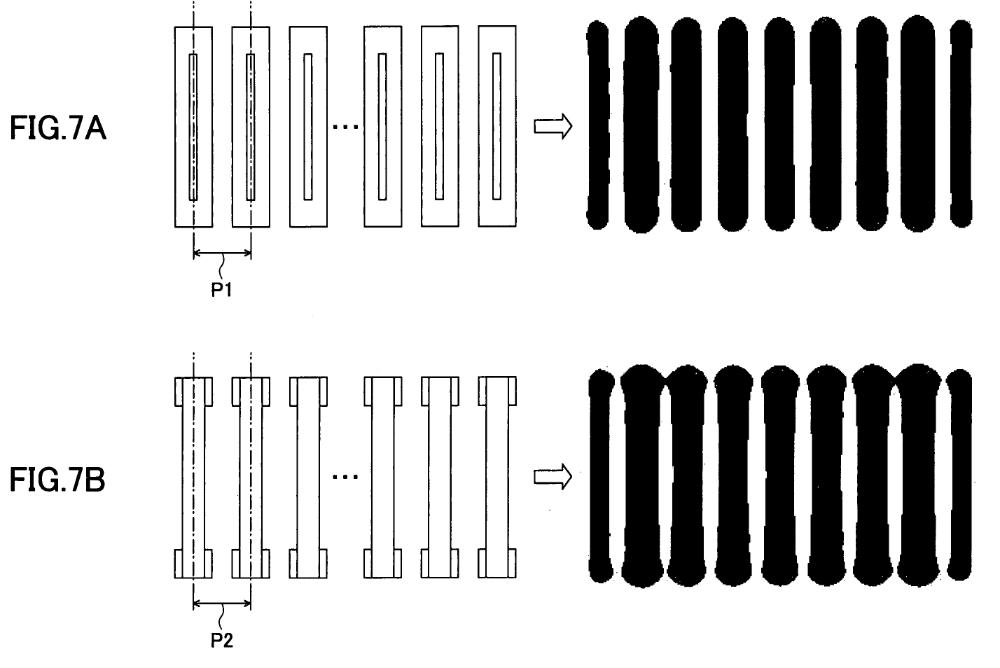

FIGS. 7A and 7B illustrates simulation results for the first example and the comparison sample. In both FIGS. 7A and 7B, mask patterns are shown on the left side and image patterns obtained by simulation are shown on the right side. The mask patterns and imaged patterns are adequately scaled in the drawings. Light source and image projection systems for simulation are selected the same as in the first example.

As shown at the left side of FIG. 7A, a mask pattern according to the first example has nine wiring patterns arranged in parallel. These wiring patterns have a longitudinal length of 750 nm, and a width of 90 nm. Auxiliary patterns have a longitudinal length of 650 nm, and a width 20 nm. The distance between the ends of the wiring pattern and the ends of the auxiliary pattern is 50 nm. Wiring pattern pitch P1 is selected as 170 nm.

On the other hand, as shown at the left side of FIG. 7B, a mask pattern according to the comparison sample has nine wiring patterns arranged in parallel. These wiring patterns have a longitudinal length of 750 nm, and a width of 90 nm. Auxiliary patterns have a longitudinal length of 50 nm, and a width 30 nm.

As shown on the right side of FIG. 7B illustrating simulation results for the comparison sample mask pattern, the shortening amount of imaged patterns is 40 nm. The shortening is suppressed, but adjacent wiring patterns are connected at some portions, making short circuits.

On the other hand, as shown on the right side of FIG. 7A illustrating simulation result for the first example mask pattern, the shortening amount of imaged patterns is still 40 nm. However, there is no connecting portion between adjacent wiring patterns, and no short circuit.

Accordingly, the mask pattern according to the first example can suppress the shortening problem while avoiding wiring pattern short circuits even when the wiring pattern pitch is decreased.

Next, mask patterns according to a first alternative example of the first embodiment are explained below.

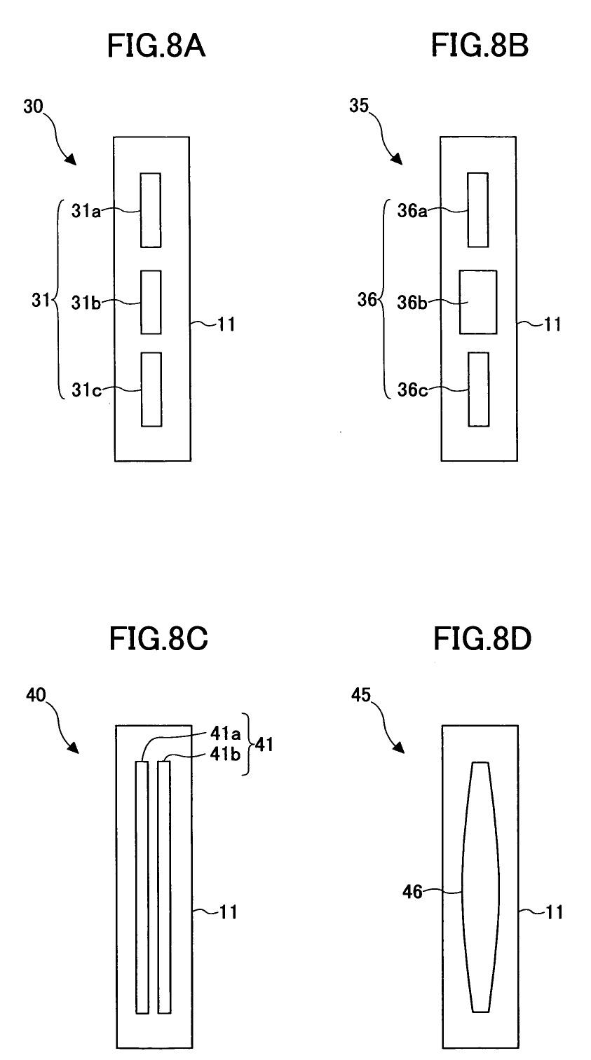

FIGS. 8A through 8D are plan views of mask patterns according to the first alternative examples of the first embodiment.

With reference to FIGS. 8A and 8B, mask patterns 30 and 35 according the first alternative example, have plural auxiliary sub-patterns 31a-31c, 36a-36c arranged serially and separately from each other inside of wiring patterns 11. The auxiliary patterns are 31 and 36.

As shown in FIG. 8A, all the sub-patterns 31a-31c may have the same width. As shown in FIG. 8B, the sub-patterns 36a-36c may have different widths. For example, a width of the middle sub-pattern 36b may be wider than the other sub-patterns 36a, 36c. In this way, illumination around the middle of the imaged plane wiring pattern is further reduced, and therefore illumination becomes further equalized over the whole wiring pattern, suppressing the shortening problem. The number of the sub-patterns is not limited to three; two, four or another number can be utilized.

As shown in FIG. 8C, a mask pattern 40 may have two auxiliary sub-patterns 41a, 41b, which are arranged in parallel inside of a wiring pattern 11. The number of the sub-patterns is not limited to two; it may be three or another number.

As shown in FIG. 8D, a mask pattern 45 may have an auxiliary pattern 46 having a bulged middle portion, which results in the same advantage as in the FIG. 8B pattern.

The auxiliary patterns shown in FIGS. 8A-8D can be combined. The auxiliary patterns shown in FIG. 8A or 8B can be arranged as shown in FIG. 8C.

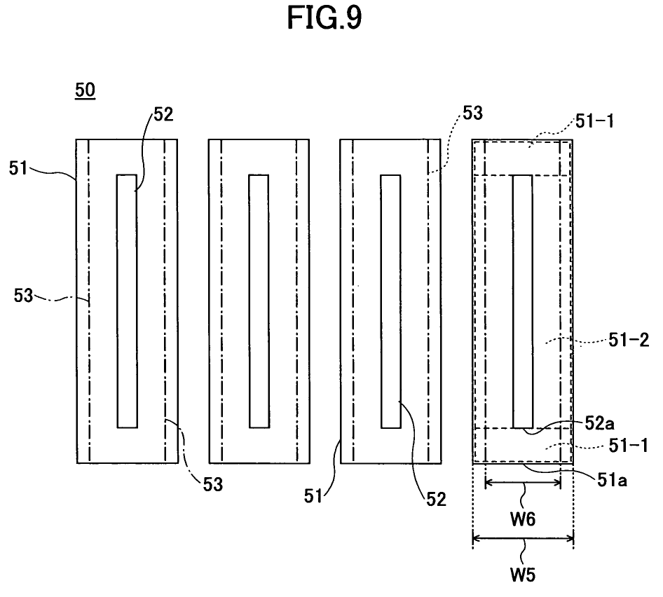

FIG. 9 is a plan view of a mask pattern according to a second alternative example of the first embodiment of the present invention.

With reference to FIG. 9, a mask pattern 50 comprises wiring patterns 51, and auxiliary patterns 52 formed within the wiring patterns 51. The mask patterns 51 are the same as the first example except that a width W5 is broader than a designed width W6 of a designed wiring pattern 53 (shown by a one dot chain line).

Since that the width W5 is broader than the designed width W6 of the designed wiring pattern 53, illumination is further equalized at first regions 51-1 at the ends of the wiring pattern 51 and at a second region 51-2. Therefore, shortening is suppressed and illumination is increased at an image-forming plane of the wiring pattern 51, and the exposure amount of the light source can be decreased. The designed wiring patterns 53 are determined by considering wiring resistances and capacities between wirings in each wiring layer but without considering shortening.

It is preferred that a ratio W5/W6 of the width W5 and the width W6 be 1.02-1.20. It is preferred that a difference between the width W5 and the width W6 be substantially equal to a width of the auxiliary pattern 52.

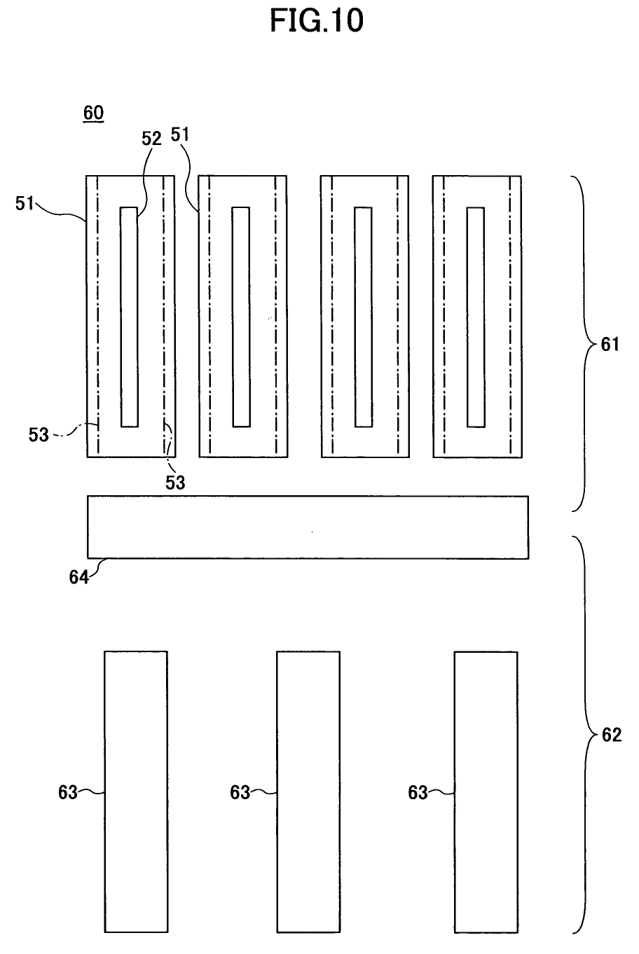

FIG. 10 is a top plan view of a mask pattern having a close or dense layout region and a sparse layout region. FIG. 10 utilizes the above mentioned second alternative example.

With reference to FIG. 10, the mask pattern 60 comprises a first mask portion 61 having densely arranged wiring patterns, and a second mask portion 62 having sparsely arranged wiring patterns. The mask pattern of the first mask portion 61 is formed by using the second alternative example mask pattern and has wiring patterns 51 having auxiliary patterns 52. The actual wiring patterns 51 are wider than designed wiring patterns 53. On the other hand, the mask patterns of the second mask portion 62 have no auxiliary patterns, and the actual wiring patterns have the same width as designed wiring patterns.

Since the wiring patterns 51 of the first mask portion 61 have the above mentioned second alternative example wiring patterns, illumination is increased at the image-forming plane of the wiring patterns 51, and is substantially the same as the illumination of the wiring patterns 63 at its image-forming plane. Therefore, it is possible to have substantially the same exposure amount of a light source for the first and second mask portions 61, 62, resulting in easy controlling of the exposure amount of the light source.

The first alternative example mask pattern, the second alternative example mask pattern and FIG. 10 mask pattern may have inverted light transparency, as above mentioned.

### Second Embodiment

A method for fabricating semiconductor devices according to a second embodiment of the present invention is now explained. A lithograph process in the semiconductor device fabrication method according to this embodiment uses an exposure mask having mask patterns according to the above mentioned first embodiment.

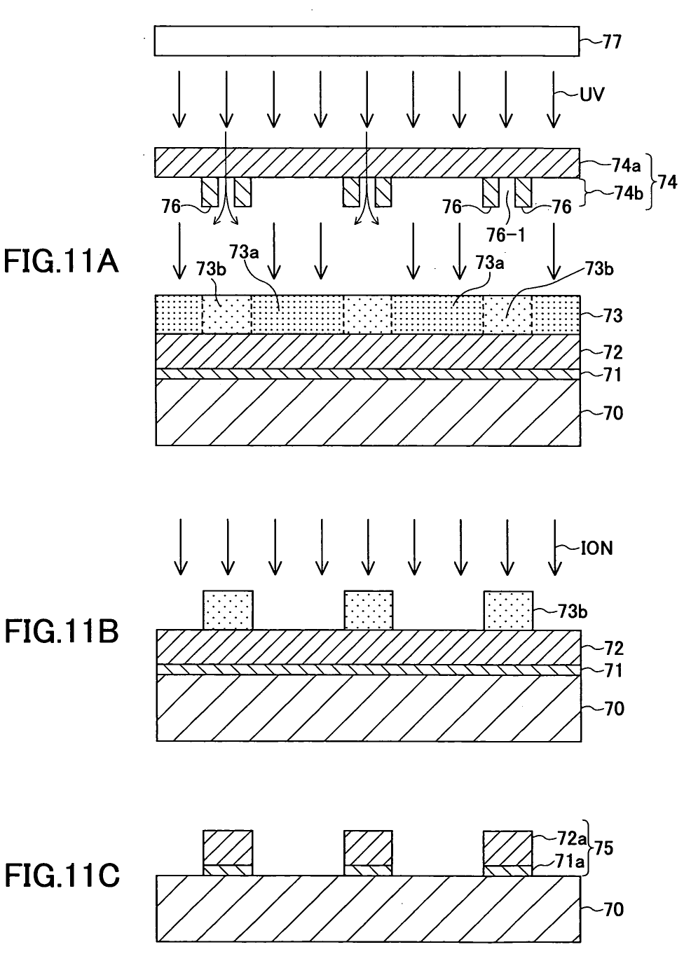

FIGS. 11A-11C illustrate the lithograph steps for fabricating semiconductor devices in accordance with the second embodiment of the present invention, in which a gate layer is formed as a gate electrode on a silicon substrate.

In the step shown by FIG. 11A, a gate oxide film 71 and a poly-silicon film 72 are formed on the silicon substrate 70. And on a surface of these films, a positive type resist film 73 is formed and then pre-baked to remove solvent from the resist film 73.

In a step shown by FIG. 11A, an exposure mask 74 having an exposure mask pattern 74b is used for the exposing process. The mask pattern 74b is, for example, the mask pattern 10 shown in FIG. 10. The inside of the wiring pattern 11 is light shielding and the auxiliary pattern 12 is transparent. As shown in FIG. 11A, gate layer patterns are formed by shielding mask films 76. The mask films 76 are provided with apertures 76-1 as auxiliary patterns.

In the exposure process, ultraviolet light is irradiated from a light source 77 of an exposure device to the exposure mask 74 to make images of the mask patterns 74b at a surface of the resist film 73, resulting in latent images 73a. Ultraviolet light transmitting through the apertures 76-1 of the mask 76 is diffused, and illumination at the gate layer pattern region 73b (dark portion) becomes uniform.

In this example where the auxiliary pattern is transparent, the exposure amount of light source is preferably defined to be smaller than in a case where no auxiliary pattern is provided, and preferably defined so as to make the exposure amount on the light receiving face as small as possible but more than a minimum threshold value for exposing the resist layer at desired regions. By weakly and equally illuminating the gate layer regions 73b and highly illuminating the exposed portions 73a and photo-etching only the portions 73a, shortening of the gate layers can be suppressed.

On the other hand, in a case where the auxiliary patterns 12 are light shielding and are inside of the wiring patterns 11, the exposure amount of the light source is preferably defined to be larger than in a case where no auxiliary pattern is provided. By increasing the illumination on the image-formed wiring pattern regions equally, shortening of the gate layers can be suppressed.

Next, in a step shown by FIG. 11B, the resist film 73 is developed and the exposed portions 73a that are the latent images are removed from the resist film 73 to form gate layer patterns 73b. Then by utilizing the gate layer patterns 73b as a mask, the poly-silicon film 72 and the gate oxide film 71 are anisotropically etched by the RIE (Reactive Ion Etching) method, for example, to form gate layers 75 each comprising a poly-silicon layer 72a and a gate oxide layer 71a.

The exposure mask 74 shown in FIG. 11A comprises a transparent substrate 74a and a shielding mask film 76. The transparent substrate 74a is made of Soda lime or Alumina silicate, etc. The shielding mask film 76 is made of an emulsion or inorganic material such as chrome, chrome oxide, silicon, silicon-germanium, etc. The mask pattern 74b is formed by the above mentioned lithography process or a similar process. A laser beam or electron beam can be used for directly writing on the resist film.

The projecting system of the exposure device of FIG. 11A may be a reducing projecting system, an enlarging projecting system or a contacting exposing system. The light source for the exposure system is not limited to ultraviolet light and may be an X-ray or an electron beam. The mask pattern 74b of the exposure mask 74 may be a mask pattern according to the first alternative example or the second alternative example of the first embodiment.

Further, the present invention is not limited to these embodiments, but various variations and modifications may be made without departing from the scope of the present invention. Prior art POC methods such as hammer head can be combined with the present invention.

The present application is based on

Japanese Priority Application No. 2004-196963 filed on Jul. 2, 2004 with the Japanese Patent Office, the entire contents of which are hereby incorporated by reference.

What is claimed is:

1. A semiconductor manufacturing method including a lithography process having an exposure step for projecting an image of a mask pattern of a mask onto a photo resist layer using exposure light,
the mask pattern comprising:
a first pattern having a light transparency characteristic, corresponding to a circuit pattern; and
a second pattern having an inverted light transparency characteristic, arranged within and spaced apart from the first pattern.

2. The semiconductor manufacturing method as claimed in claim 1, wherein the second pattern is small enough so that no image of the second pattern is projected onto the photo resist layer.

3. The semiconductor manufacturing method as claimed in claim 1, wherein there are predetermined spaces between longitudinal ends of the first pattern and longitudinal ends of the second pattern.

4. The semiconductor manufacturing method as claimed in claim 1, wherein the second pattern is arranged along the longitudinal direction of the first pattern.

5. The semiconductor manufacturing method as claimed in claim 4, wherein longitudinal sides of the second pattern are parallel with longitudinal sides of the first pattern.

6. The semiconductor manufacturing method as claimed in claim 4, wherein the second pattern comprises a plurality of sub-patterns arranged along the longitudinal direction of the first pattern.

7. The semiconductor manufacturing method as claimed in claim 1, wherein the second pattern comprises a plurality of sub-patterns arranged along width direction of the first pattern.

8. The semiconductor manufacturing method as claimed in claim 1, wherein a width of the first pattern is larger than a width of a designed first pattern.

9. The semiconductor manufacturing method as claimed in claim 1, wherein a width of the second pattern is within the range of 2%-20% of a wavelength of the exposure light.

10. The semiconductor manufacturing method as claimed in claim 1, wherein a width of the second pattern is within the range of 4 nm-40 nm when a wavelength of the exposure light is 193 nm.

11. The semiconductor manufacturing method as claimed in claim 1, wherein the first pattern is light transparent and the second pattern and a region outside of the first pattern are shielding; and
an exposure amount of the exposure light is larger than in a case where no second pattern is provided.

12. The semiconductor manufacturing method as claimed in claim 1, wherein the first pattern is shielding and the second pattern and a region outside of the first pattern are transparent; and
an exposure amount of the exposure light is smaller than in a case where no second pattern is provided.

13. A method for manufacturing a semiconductor device including a first region having close gate patterns and a second region having sparse gate patterns, including a lithography process having an exposure step for projecting an image of a mask pattern of a mask onto a photo resist layer of the semiconductor device using exposure light,
the mask pattern comprising:
in a region corresponding to the first region, a first pattern being light shielding and corresponding to the gate electrode patterns, and a second pattern being light transparent and arranged within and spaced apart from the first pattern; and
in a region corresponding to the second region, a third pattern being light shielding and corresponding to the gate electrode patterns;
wherein a width of the first pattern is larger than a width of the third pattern.

14. The method as claimed in claim 13, wherein the second pattern is small enough so that no image of the second pattern is projected onto the photo resist layer.

15. The method as claimed in claim 13, wherein there are predetermined spaces between longitudinal ends of the first pattern and longitudinal ends of the second pattern.

16. A method for manufacturing a semiconductor device including a first region having close wiring patterns and a second region having sparse wiring patterns, including a lithography process having an exposure step for projecting an image of a mask pattern of a mask onto a photo resist layer of the semiconductor device using exposure light,
the mask pattern comprising:
in a region corresponding to the first region, a first pattern being light transparent and corresponding to the wiring patterns, and a second pattern being light shielding and arranged within and separated from the first pattern; and
in a region corresponding to the second region, a third pattern being light transparent and corresponding to the wiring patterns;
wherein a width of the first pattern is larger than a width of the third pattern.

17. The method as claimed in claim 16, wherein the second pattern is small enough so that no image of the second pattern is projected onto the photo resist layer.

18. The method as claimed in claim 16, wherein there are predetermined spaces between longitudinal ends of the first pattern and longitudinal ends of the second pattern.

19. An exposure mask including a mask pattern for forming a circuit pattern on a semiconductor device, the mask pattern comprising:
a first pattern having a light transparency characteristic, corresponding to the circuit pattern;
a second pattern having an inverted light transparency characteristic, arranged within and spaced apart from the first pattern.

20. The exposure mask as claimed in claim 19, wherein the second pattern is small enough so that no image of the second pattern is projected onto the photo resist layer.

21. The method as claimed in claim 19, wherein there are predetermined spaces between longitudinal ends of the first pattern and longitudinal ends of the second pattern.
